(19) United States
(12) Patent Application Publication
(10) Pub. No.: US 2026/0246255 A1
(43) Pub. Date: Aug. 20, 2026

(54) LIQUID COOLED BUSBAR ASSEMBLY

(71) Applicant: Delta Electronics, Inc., Taoyuan City (TW)

(72) Inventors: Ming-Tang Yang, Taoyuan City (TW); Kun-Cheng Mao, Taoyuan City (TW); Jhih-Hao Chen, Taoyuan City (TW); Chih-Yung Huang, Taoyuan City (TW)

(21) Appl. No.: 19/423,839

(22) Filed: Dec. 17, 2025

Related U.S. Application Data
(60) Provisional application No. 63/760,824, filed on Feb. 20, 2025.

(30) Foreign Application Priority Data
Jun. 11, 2025 (CN) 202510775271.2

(51) Int. Cl. H02G 5/10; H05K 7/20

(52) U.S. Cl. CPC H02G 5/10; H05K 7/20272

(57) ABSTRACT

A liquid cooled busbar assembly is disclosed and includes a first busbar, a second busbar, an insulation element and a water-cooling plate. The first busbar is extended along a first direction and includes a first connection interface electrically connected with an electrical device. The second busbar is extended along the first direction and includes a second connection interface electrically connected with the electrical device. The insulation element is disposed between the first connection interface and the second connection interface to electrically insulate the first connection interface and the second connection interface. The water-cooling plate is in contact with rear ends of the first busbar and the second busbar simultaneously, electrically insulated from the first busbar and the second busbar, and includes a liquid channel extended along the first direction. The liquid channel allows a coolant to flow therethrough to cool the first busbar and the second busbar.

### CROSS-REFERENCE TO RELATED APPLICATION

This application claims the benefit of U.S. Provisional Application No. 63/760,824 filed on February 20, 2025, and entitled “WATER-COOLING BUSBAR”. This application claims priority to China Patent Application No. 202510775271.2 filed on June 11, 2025. The entireties of the above-mentioned patent applications are incorporated herein by reference for all purposes.

### FIELD OF THE INVENTION

The present disclosure relates to a busbar structure, and more particularly to a liquid cooled busbar assembly having the water-cooling plate with the liquid channel design, so that the heat dissipation surface is directly thermally coupled to the two busbars blocked by the insulation element, and the heat dissipation efficiency is effectively improved.

### BACKGROUND OF THE INVENTION

With the increasing development of information technology, the application of data centers has become more and more extensive and important. A system cabinet for general data centers usually contain a plurality of servers. In order to meet the power supply requirements of multiple servers in one system cabinet, most of the conventional data centers use a system busbar structure for plugging multiple busbar connectors connected to each server so that the system busbar can supply the power to each server. However, when the system busbar supplies the power to the multiple servers with high current for a long time, a large amount of heat energy is generated, thereby affecting the power transmission efficiency and service life of the system busbar.

In the prior art, two sets of water-cooling plates are connected in series and attached to both sides of the system busbar for heat dissipation, and different water-cooling plates need to be connected in series by using external hoses. Although the heat dissipation effect is achieved, the cost and the overall volume of the water-cooling plates are difficult to be adopted by the market, and the risk of coolant leakage is increased.

Therefore, there is a need of providing a liquid cooled busbar assembly having the water-cooling plate with the liquid channel design, so that the heat dissipation surface is directly thermally coupled to the two busbars blocked by the insulation element, the heat dissipation efficiency is effectively improved, and the drawbacks encountered by the prior arts are obviated.

### SUMMARY OF THE INVENTION

An object of the present disclosure is to provide a liquid cooled busbar assembly having the water-cooling plate with the liquid channel design, so that the heat dissipation surface is directly thermally coupled to the two busbars blocked by the insulation element, and the heat dissipation efficiency is effectively improved.

Another object of the present disclosure is to provide a liquid cooled busbar assembly. For a liquid cooled busbar assembly extended vertically, a water-cooling plate with one single-structure is provided to be thermally coupled to the opposite inner surfaces of the two busbars, or to be thermally coupled to the rear ends of the two busbars, and the water-cooling plate maintains the electrical insulation with the two busbars. In that, at least one liquid channel of the water-cooling plate allows a coolant to flow through to cool the heat generated by the two busbars simultaneously. When the water-cooling plate with one single structure is thermally coupled to the rear ends of the two busbars through the front end surface, the connection interfaces included in the front ends of the two busbars collaboratively form a plug-in interface through an insulation element for electrical connection of multiple electrical devices vertically arranged. The inlet and the outlet for the coolant are connected to the rear end surface of the water-cooling plate. Preferably but not exclusively, the inlet and the outlet are led in and led out through the bottom end or the top end, and do not interfere with the connection between the electrical devices and the plug-in interface. In addition, when the water-cooling plate with one single-structure is sandwiched between two busbars, the water-cooling plate is designed to have a first liquid channel and a second liquid channel for cooling the two busbars simultaneously. The coolant flows through the first liquid channel and the second liquid channel in opposite directions, respectively, which are in communication, for example, at the top of the water-cooling plate. The first liquid channel and the second liquid channel are formed by two tubes arranged side by side and in communication with each other. Alternatively, the first liquid channel and the second liquid channel are formed by dividing the internal space of the water-cooling plate by a flat partition plate or a bent partition plate. Thereby, the water-cooling plate with one single-structure can provide effective heat dissipation performance between two busbars. In addition, the inlet and the outlet for the coolant are connected through the elongated sides of the water-cooling plate, which does not interfere with the connection of the electrical devices with the front plug-in interfaces of the two busbars. Furthermore, the liquid cooled busbar assembly of the present disclosure utilizes the combination of the one single-structure water-cooling plate and the two busbars to form the cooling system, so that a smaller space is occupied, and the positions of the inlet and the outlet do not interfere with the use of the front-end plug-in interface. It is easy to further assemble an outer housing to provide the structural support and the protection. Certainly, the present disclosure is not limited thereto.

In accordance with an aspect of the present disclosure, a liquid cooled busbar assembly is provided and includes a first busbar, a second busbar, an insulation element and a water-cooling plate. The first busbar is extended along a first direction and includes a first connection interface configured to be electrically connected with an electrical device to supply power to the electrical device. The second busbar is extended along the first direction and includes a second connection interface configured to be electrically connected with the electrical device to provide a power loop path for the electrical device. The insulation element is disposed between the first connection interface and the second connection interface to electrically insulate the first connection interface and the second connection interface. The water-cooling plate is in contact with rear ends of the first busbar and the second busbar simultaneously, electrically insulated from the first busbar and the second busbar, and includes a liquid channel extended along the first direction, wherein the liquid channel allows a coolant to flow therethrough to cool the first busbar and the second busbar.

In an embodiment, the insulation element is extended along the first direction, and the first connection interface and the second connection interface collaboratively form a plug-in interface through the insulation element for connecting the electrical device.

In an embodiment, the liquid cooled busbar assembly further includes an inlet and an outlet, wherein the inlet and the outlet are respectively disposed adjacent to a top end and a bottom end of the water-cooling plate, in communication with the at least one liquid channel, and configured to guide the coolant into or out of the at least one liquid channel.

In an embodiment, the water-cooling plate includes a first elongated side plate and a second elongated side plate, the first elongated side plate and the second elongated side plate are spaced apart from each other in a second direction, the second direction is perpendicular to the first direction, the at least one liquid channel is formed between the first elongated side plate and the second elongated side plate, the first elongated side plate is thermally connected to the rear ends of the first busbar and the second busbars, and the inlet and the outlet are respectively parallel to the second direction and in communication with the at least one liquid channel through the second elongated side plate.

In an embodiment, the liquid cooled busbar assembly further includes an outer housing, wherein the outer housing is extended along the first direction, surrounds the first busbar, the second busbar and the water-cooling plate, and includes an open end, wherein the open end faces a second direction, and the second direction is perpendicular to the first direction, wherein the open end is spatially corresponding to the first connection interface and the second connection interface, and the first connection interface and the second connection interface are exposed through the open end.

In an embodiment, the outer housing includes a pair of spacers, which are respectively arranged on two opposite sides of the open end, wherein the first connection interface and the second connection interface collaboratively form a plug-in interface through the insulation element and the pair of spacers, and the plug-in interface faces the second direction for connecting the electrical device.

In accordance with another aspect of the present disclosure, a liquid cooled busbar assembly is provided and includes a first busbar, a second busbar, an insulation element and a water-cooling plate. The first busbar is extended along a first direction and includes a first connection interface configured to be electrically connected with an electrical device to supply power to the electrical device. The second busbar is extended along the first direction and includes a second connection interface configured to be electrically connected with the electrical device to provide a power loop path for the electrical device. The insulation element is disposed between the first connection interface and the second connection interface to electrically insulate the first connection interface and the second connection interface. The water-cooling plate is disposed between the first busbar and the second busbar, electrically insulated from the first busbar and the second busbar, and includes a liquid channel extended along the first direction, wherein the liquid channel allows a coolant to flow therethrough to cool the first busbar and the second busbar.

In an embodiment, the insulation element is extended along the first direction, and the first connection interface and the second connection interface collaboratively form a plug-in interface through the insulation element for connecting the electrical device.

In an embodiment, the water-cooling plate includes a first elongated side plate and a second elongated side plate, the first elongated side plate and the second elongated side plate are parallel to a second direction, the second direction is perpendicular to the first direction, and the at least one liquid channel is located between the first elongated side plate and the second elongated side plate, wherein the first elongated side plate and the second elongated side plate respectively form a first heat dissipation surface and a second heat dissipation surface, which are thermally coupled to lateral sides of the first busbar and the second busbar, wherein the first heat dissipation surface and the second heat dissipation surface are two surfaces opposite to each other in a third direction, and the third direction is perpendicular to the second direction and perpendicular to the first direction.

In an embodiment, the water-cooling plate further includes a partition plate, the partition plate is arranged in the at least one liquid channel and parallel to the first elongated side plate and the second elongated side plate, and the partition plate divides the at least one liquid channel into a first liquid channel and a second liquid channel.

In an embodiment, the water-cooling plate further includes a partition plate, the partition plate is disposed in the at least one liquid channel, bent and connected between the first elongated side plate and the second elongated side plate, and the partition plate divides the at least one liquid channel into a first liquid channel and a second liquid channel.

In an embodiment, the water-cooling plate further includes an inlet and an outlet, and the inlet and the outlet are disposed adjacent to a bottom end of the water-cooling plate and in communication with the first liquid channel and the second liquid channel through the first elongated side plate and the second elongated side plate, respectively.

In an embodiment, the water-cooling plate further includes a top-end cover and a bottom-end cover, and the top-end cover and the bottom-end cover are detachably connected to a top end and a bottom end of the water-cooling plate, respectively, wherein the top-end cover allows the first liquid channel and the second liquid channel to communicate with each other, and the bottom-end cover blocks the first liquid channel and the second liquid channel.

In an embodiment, the liquid cooled busbar assembly further includes an outer housing, wherein the outer housing is extended along the first direction, surrounds the first busbar, the second busbar and the water-cooling plate, and includes an open end, wherein the open end faces a second direction, and the second direction is perpendicular to the first direction, wherein the open end is spatially corresponding to the first connection interface and the second connection interface, and the first connection interface and the second connection interface are exposed through the open end.

In an embodiment, the outer housing includes a pair of spacers, which are respectively arranged on two opposite sides of the open end, wherein the first connection interface and the second connection interface collaboratively form a plug-in interface through the insulation element and the pair of spacers, and the plug-in interface faces the second direction for connecting the electrical device.

In accordance with a further aspect of the present disclosure, a liquid cooled busbar assembly is provided and includes a water-cooling plate, a first busbar and a second busbar. The water-cooling plate is extended along a first direction and includes at least one liquid channel, wherein the liquid channel allows a coolant to flow therethrough and forms at least one heat dissipation surface. The first busbar is extended along a first direction, thermally coupled with the at least one heat dissipation surface, and includes a first connection interface configured to be electrically connected with an electrical device to supply power to the electrical device. The second busbar is extended along the first direction, thermally coupled with the at least one heat dissipation surface, and includes a second connection interface configured to be electrically connected with the electrical device to provide a power loop path for the electrical device, wherein the first connection interface and the second connection interface are insulated by an insulation element and collaboratively form a plug-in interface for connecting the electrical device. The water-cooling plate includes an inlet and an outlet arranged at a bottom end thereof, and the coolant is introduced into the water-cooling plate through the inlet, flows through the at least one heat dissipation surface, and then is discharged out of the water-cooling plate through the outlet.

In an embodiment, the insulation element is extended along the first direction, and the first connection interface and the second connection interface collaboratively form a plug-in interface through the insulation element for connecting the electrical device.

In an embodiment, the at least one liquid channel includes a first liquid channel and a second liquid channel, and the first liquid channel and the second liquid channel are arranged along a second direction, located between the first busbar and the second busbar, and electrically insulated from the first busbar and the second busbar, wherein the second direction is perpendicular to the first direction, and the coolant flows through the first liquid channel and the second liquid channel in opposite directions.

In an embodiment, the water-cooling plate further includes a top-end cover detachably connected to a top end of the water-cooling plate, wherein the top-end cover allows the first liquid channel and the second liquid channel to communicate with each other.

In an embodiment, the inlet and the outlet are in communication with the first liquid channel and the second liquid channel through the first busbar and the second busbar, respectively.

In an embodiment, the inlet and the outlet are in communication with the first liquid channel and the second liquid channel, respectively, through the first busbar or the second busbar.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1 is a perspective structural view illustrating a liquid cooled busbar assembly according to a first embodiment of the present disclosure from a rear-end perspective.;

FIG. 2 is a perspective structural view illustrating the liquid cooled busbar assembly according to the first embodiment of the present disclosure from a front-end perspective;

FIG. 3 is a top view illustrating the liquid cooled busbar assembly according to the first embodiment of the present disclosure;

FIG. 4 is a cross-sectional structural view illustrating the liquid cooled busbar assembly according to the first embodiment of the present disclosure;

FIG. 5 is a top view illustrating the liquid cooled busbar assembly of FIG. 4;

FIG. 6 is a perspective structural view illustrating a liquid cooled busbar assembly according to a second embodiment of the present disclosure from a front-end perspective;

FIG. 7 is a cross-sectional structural view illustrating the liquid cooled busbar assembly according to the second embodiment of the present disclosure;

FIG. 8 is a top view illustrating the liquid cooled busbar assembly of FIG. 7;

FIG. 9 is a vertical cross-sectional structure of the water-cooling plate in the liquid cooled busbar assembly according to the second embodiment of the present disclosure;

FIG. 10 is a horizontal cross-sectional structure of the water-cooling plate in the liquid cooled busbar assembly according to the second embodiment of the present disclosure;

FIG. 11 is a cross-sectional structural view illustrating a liquid cooled busbar assembly according to a third embodiment of the present disclosure;

FIG. 12 is a horizontal cross-sectional structure of the water-cooling plate in the liquid cooled busbar assembly according to the third embodiment of the present disclosure;

FIG. 13 is a perspective structural view illustrating a liquid cooled busbar assembly according to a fourth embodiment of the present disclosure from a front-end perspective;

FIG. 14 is a top view illustrating the liquid cooled busbar assembly according to the fourth embodiment of the present disclosure;

FIG. 15 is a cross-sectional structural view illustrating the liquid cooled busbar assembly according to the fourth embodiment of the present disclosure;

FIG. 16 is a vertical cross-sectional structure of the water-cooling plate in the liquid cooled busbar assembly according to the fourth embodiment of the present disclosure; and

FIG. 17 is a vertical cross-sectional structure of a water-cooling plate in a liquid cooled busbar assembly according to a fifth embodiment of the present disclosure.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “upper,” “lower,” “top,” “bottom,” “inner,” “outer” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When an element is referred to as being “connected,” or “coupled,” to another element, it can be directly connected or coupled to the other element or intervening elements may be present. Although the wide numerical ranges and parameters of the present disclosure are approximations, numerical values are set forth in the specific examples as precisely as possible. In addition, although the "first," "second" and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments. Besides, "and / or" and the like may be used herein for including any or all combinations of one or more of the associated listed items.

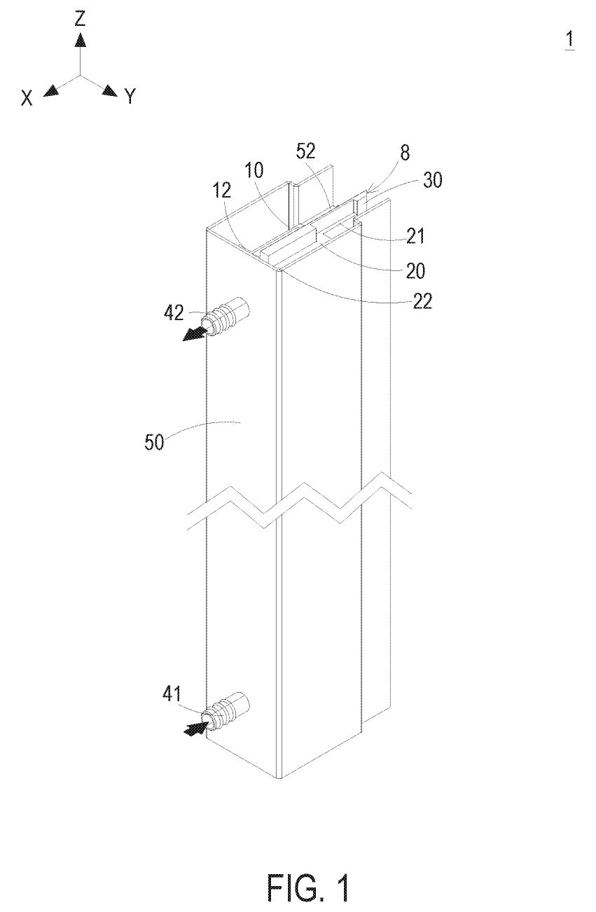

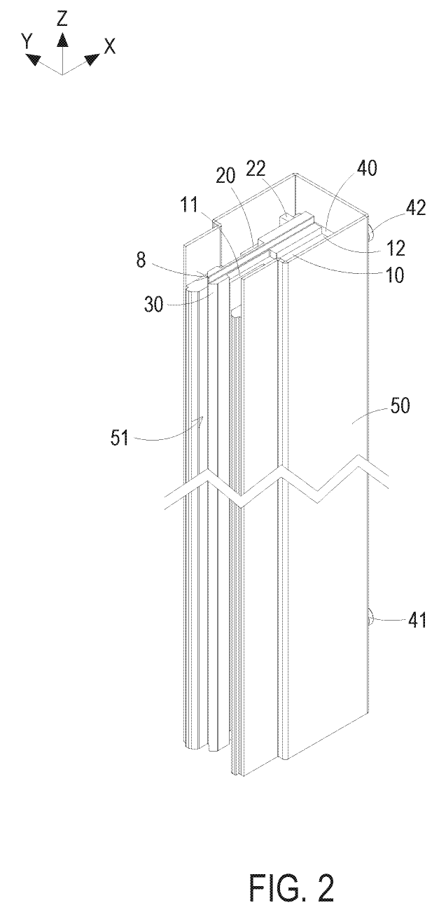

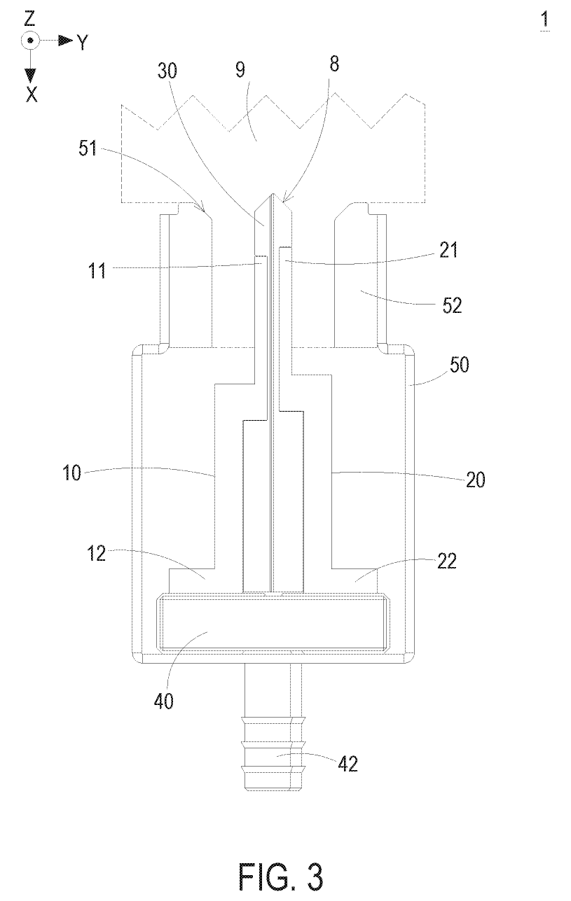

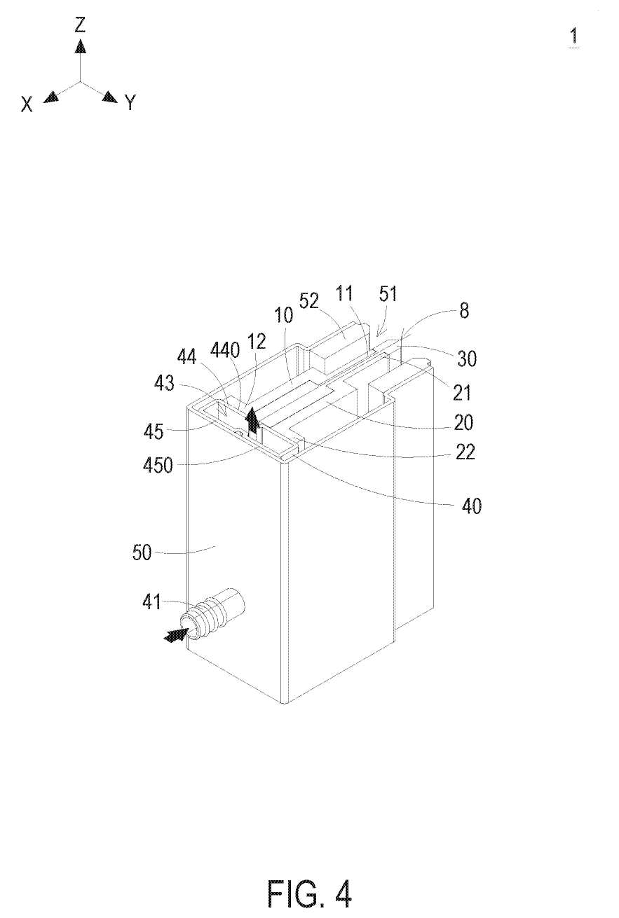

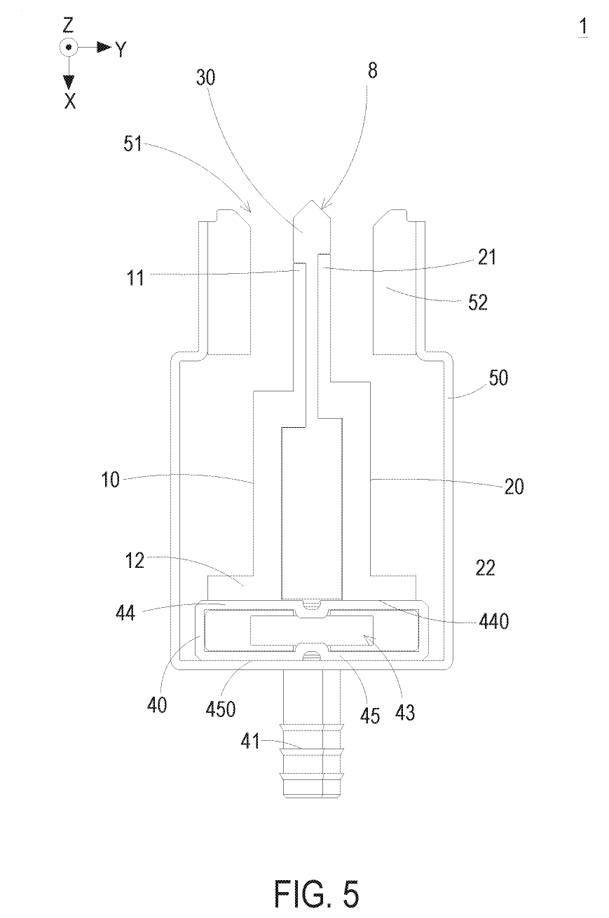

FIG. 1 and FIG. 2 are perspective structural views illustrating a liquid cooled busbar assembly according to a first embodiment of the present disclosure. FIG. 3 is a top view illustrating the liquid cooled busbar assembly according to the first embodiment of the present disclosure. FIG. 4 and FIG. 5 show a cross-sectional structure of the liquid cooled busbar assembly according to the first embodiment of the present disclosure. The present disclosure provides a liquid cooled busbar assembly1 including a first busbar 10, a second busbar 20, an insulation element 30 and a water-cooling plate 40. Preferably but not exclusively, the first busbar 10 and the second busbar 20 are copper busbars arranged in pair. In the embodiment, the first busbar 10 is extended along a first direction (i.e., the Z axial direction) and includes a first connection interface 11, which faces a second direction (i.e., the reverse X axial direction) and is configured to be electrically connected with an electrical device 9 to supply power to the electrical device 9. Similarly, the second busbar 20 is extended along the first direction (i.e., the Z axial direction) and includes a second connection interface 21, which faces the second direction (i.e., the reverse X axial direction) and is configured to be electrically connected with the electrical device 9 to provide a power loop path for the electrical device 9. The insulation element 30 is disposed between the first connection interface 11 and the second connection interface 21 to electrically insulate the first connection interface 11 and the second connection interface 21, so that the first busbar 10 and the second busbar 20 are electrically insulated with each other simultaneously. In the embodiment, the water-cooling plate 40 is extended along the first direction (i.e., the Z axial direction), in contact with a rear end 12 of the first busbar 10 and a rear end 22 of the second busbar simultaneously, and electrically insulated from the first busbar 10 and the second busbar 20. Certainly, the type of electrical insulation between the water-cooling plate 40 and the first busbar 10 and the second busbar 20 is adjustable according to the practical requirements. Preferably but not exclusively, in an embodiment, an insulation layer is disposed thereon or an insulation paint is sprayed thereon. In the embodiment, the water-cooling plate 40 includes a liquid channel 43 extended along the first direction (i.e., the Z axial direction). The liquid channel 43 allows a coolant to flow therethrough, so as to dissipate heat generated by the first busbar 10 and the second busbar 20.

In the embodiment, the insulation element 30 is also extended along the first direction (i.e., the Z axial direction), and the first connection interface 11 and the second connection interface 21 collaboratively form a plug-in interface 8 through the insulation element 30 for connecting the electrical device 9. Notably, each bottom end and each top end of the first busbar 10, the second busbar 20, the insulation element 30 and the water-cooling plate 40 extended along the first direction (i.e., the Z axial direction) are not essential technical features to limit the present disclosure. The liquid cooled busbar assembly 1 is allowed to extend along the first direction (i.e., the Z axial direction) to form a common plug-in interface 8 for a plurality of electrical devices 9. The plurality of electrical devices 9 are arranged along the first direction (i.e., the Z axial direction), and respectively connected to the plug-in interface 8 along the X axial direction to provide the power. For ease of explanation, the present disclosure is only presented in terms of a partial section structure and is not limited thereto.

In the embodiment, the liquid cooled busbar assembly 1 further includes an inlet 41 and an outlet 42. The inlet 41 and the outlet 42 are respectively disposed adjacent to the bottom end and the top end of the water-cooling plate 40 and in communication with at least one liquid channel 43 to guide the coolant (not shown) into or out of the at least one liquid channel 43. In the embodiment, the inlet 41 is located at the bottom end, the outlet 42 is located at the top end, and the coolant is transported upward from bottom to top along the Z axial direction. In another embodiment, the inlet 41 is located at the top end, the outlet 42 is located at the bottom end, and the coolant is transported downward from top to bottom along the reverse Z axial direction. In other embodiments, the positions of the inlet 41 and the outlet 42 , the flow direction of the coolant and the type of the at least one liquid channel 43 are adjustable according to the practical requirements, and the present disclosure is not limited thereto. From the above, when the single-structure water-cooling plate 40 is thermally coupled to the rear end 12 of the first busbar 10 and the rear end 22 of the second busbar 20 with the first surface 440, the connection interfaces included in the front ends of the two busbars collaboratively form the plug-in interface 8 through the insulation element 30 for electrical connection of the plurality of electrical devices 9 arranged vertically. The inlet 41 and the outlet 42 for the coolant are connected through the second surface 450 of the water-cooling plate 40, but not limited to the bottom end or the top end for introduction or export. Moreover, the connection between the electrical device 9 and the plug-in interface 8 is not interfered by the arrangements of the inlet 41 and the outlet 42.

In the embodiment, the water-cooling plate 40 includes a first elongated side plate 44 and a second elongated side plate 45. The first elongated side plate 44 and the second elongated side plate 45 are spaced apart from each other in the second direction (i.e., the reverse X axial direction), and the second direction is perpendicular to the first direction. The at least one liquid channel 43 is formed between the first elongated side plate 44 and the second elongated side plate 45. The first elongated side plate 44 includes the first surface 440 served as a heat dissipation surface to be thermally connected to the rear end 12 of the first busbar 10 and the rear end 22 of the second busbar 20. The inlet 41 and the outlet 42 are respectively parallel to the second direction (i.e., the reverse X axial direction), and in communication with the at least one liquid channel 43 through the second surface 450 of the second elongated side plate 45.

In the embodiment, the liquid cooled busbar assembly 1 further includes an outer housing 50. The outer housing 50 is extended along the first direction (i.e., the Z axial direction), surrounds the first busbar 10, the second busbar 20 and the water-cooling plate 40, and includes an open end 51. The open end faces the second direction (i.e., the reverse X axial direction), and the second direction is perpendicular to the first direction. The open end 51 is spatially corresponding to the first connection interface 11 and the second connection interface 21, and allows the first connection interface 11 and the second connection interface 21 to be exposed through the open end 51. In the embodiment, the outer housing 50 includes a pair of spacers 52, which are respectively arranged on two opposite sides of the open end 51. The first connection interface 11 and the second connection interface 21 collaboratively form the plug-in interface 8 through the insulation element 30 and the pair of spacers 52. The plug-in interface 8 faces the second direction (i.e., the reverse X axial direction) for connecting the electrical device 9. The application of the plurality of electrical devices 9 and the common plug-in interface 8 is as described above and not redundantly described herein. Furthermore, in the embodiment, the second surface 450 of the second elongated side plate 45 of the water-cooling plate 40 is attached to the inner wall surface of the outer housing 50, and the inlet 41 at the bottom end and the outlet 42 at the top end are disposed through the outer housing 50. In other embodiments, the outer housing 50 can also easily avoid the inlet 41 and the outlet 42 at the bottom end and the top end thereof. Notably, the liquid cooled busbar assembly 1 of the present disclosure utilizes the combination of the one single-structure water-cooling plate 40 and both of the first busbar 10 and the second busbar 20. The assembling is easy and a smaller space is occupied. The positions of the inlet 41 and the outlet 42 do not interfere with the use of the front-end plug-in interface 8, and it is easy to further assemble the outer housing 50 to provide the structural support and the protection. Certainly, the present disclosure is not limited thereto.

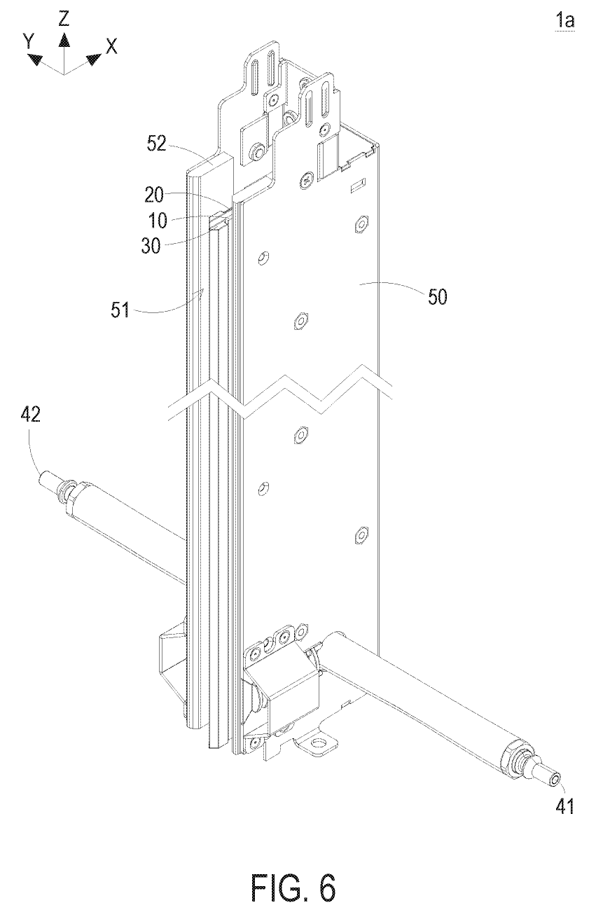

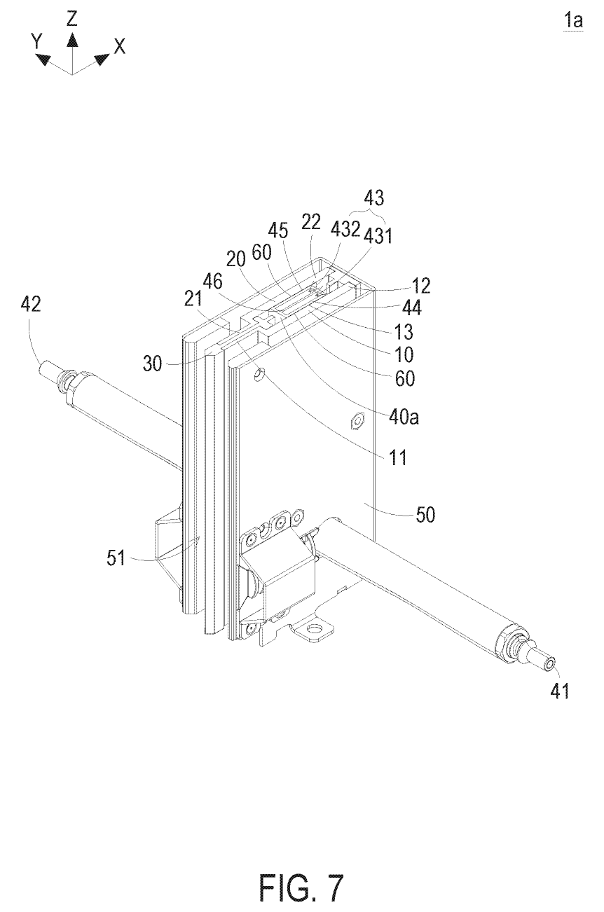

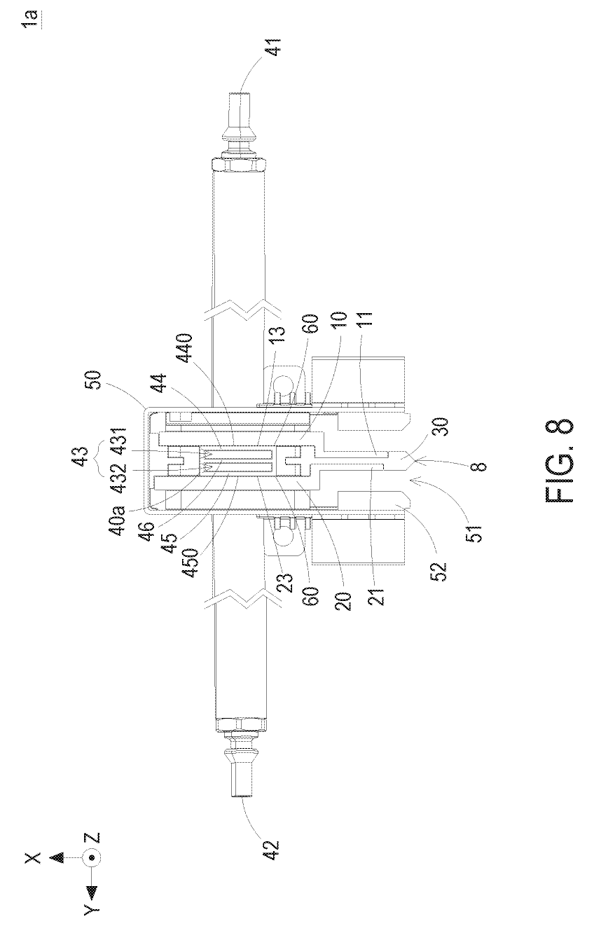

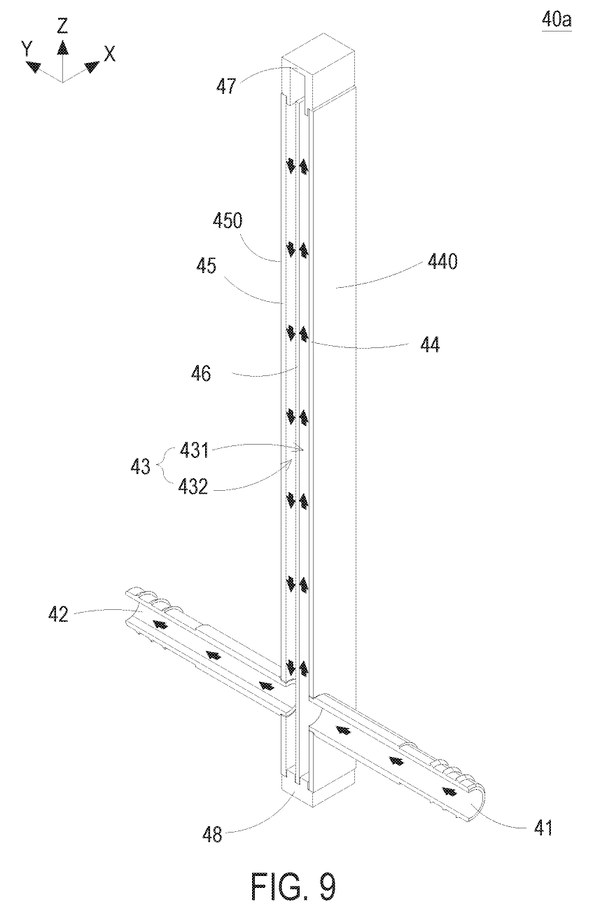

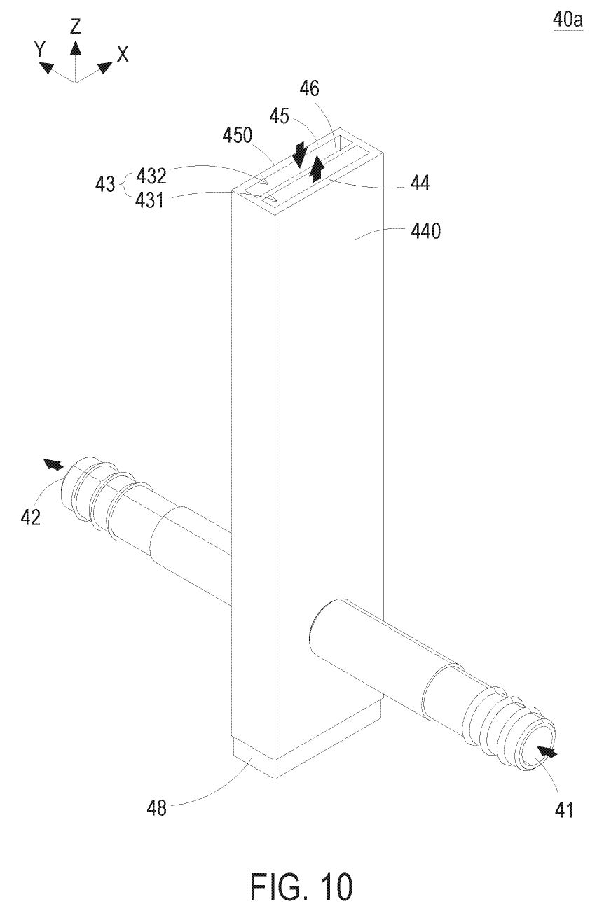

FIG. 6 is a perspective structural view illustrating a liquid cooled busbar assembly according to a second embodiment of the present disclosure from a front-end perspective. FIG. 7 and FIG. 8 show a cross-sectional structure of the liquid cooled busbar assembly according to the second embodiment of the present disclosure. FIG. 9 is a vertical cross-sectional structure of the water-cooling plate in the liquid cooled busbar assembly according to the second embodiment of the present disclosure. FIG. 10 is a horizontal cross-sectional structure of the water-cooling plate in the liquid cooled busbar assembly according to the second embodiment of the present disclosure. In the embodiment, the structures, elements and functions of the liquid cooled busbar assembly 1a are similar to those of the liquid cooled busbar assembly 1 of FIG. 1 to FIG. 5, and are not redundantly described herein. In the embodiment, the liquid-cooled busbar assembly 1a also includes a first busbar 10, a second busbar 20, an insulation element 30 and a water-cooling plate 40a. Different from the aforementioned embodiments, in the embodiment, the water-cooling plate 40a is disposed between the first busbar 10 and the second busbar 20, and electrically insulated from the first busbar 10 and the second busbar 20, and includes at least one liquid channel 43 extended along the first direction (i.e., the Z axial direction). The at least one liquid channel 43 the coolant to flow therethrough to simultaneously dissipate the heat generated by the first busbar 10 and the second busbar 20.

In the embodiment, the water-cooling plate 40a includes a first elongated side plate 44 and a second elongated side plate 45, which are parallel to the second direction (i.e., the reverse X axial direction). Moreover, the at least one liquid channel 43 is located between the first elongated side plate 44 and the second elongated side plate 45. In the embodiment, the first surface 440 of the first elongated side plate 44 and the second surface 450 of the second elongated side plate 45 respectively form a first heat dissipation surface and a second heat dissipation surface, which are thermally connected to a lateral side 13 of the first busbar 10 and a lateral side 23 of the second busbar 20. The first heat dissipation surface (i.e., the first surface 440 ) and the second heat dissipation surface (i.e., the second surface 450 ) are two surfaces opposite to each other in a third direction (i.e., the Y axial direction), and the third direction is perpendicular to the second direction and also perpendicular to the first direction. In the embodiment, an insulation and heat-conductive thermal interface material layer 60 is further provided. Preferably but not exclusively, the insulation and heat-conductive thermal interface material layer 60 is disposed between the first surface 440 of the first elongated side plate 44 of the water-cooling plate 40a and the lateral side 13 of the first busbar 10, and between the second surface 450 of the second elongated side plate 45 of the water-cooling plate 40a and the lateral side 23 of the second busbar 20, so as to enhance the thermal coupling and insulation between the water-cooling plate 40a to the first busbar 10 and the second busbar 20. Certainly, the present disclosure is not limited thereto.

In the embodiment, the water-cooling plate 40a further includes a partition plate 46. Preferably but not exclusively, the partition plate 46 is arranged in the at least one liquid channel 43, and parallel to the first elongated side plate 44 and the second elongated side plate 45, that is, parallel to the second direction (i.e., the reverse X axial direction). Moreover, the partition plate 46 divides the at least one liquid channel 43 into a first liquid channel 431 and a second liquid channel 432. In the embodiment, the water-cooling plate 40a further includes an inlet 41 and an outlet 42 disposed adjacent to the bottom end of the water-cooling plate 40a and parallel to the third direction (i.e., the Y axial direction). The inlet 41 is in communication with the first liquid channel 431 through the first elongated side plate 44, and the outlet 42 is in communication with the second liquid channel 432 through the second long side plate 45. Further, in the embodiment, the water-cooling plate 40a further includes a top-end cover 47 and a bottom-end cover 48. The top-end cover 47 and the bottom-end cover 48 are detachably connected to the top end and the bottom end of the water-cooling plate 40a, respectively. The top-end cover 47 includes a communication structure, which allows the first liquid channel 431 and the second liquid channel 432 to communicate with each other, and the bottom-end cover 48 blocks the first liquid channel 431 and the second liquid channel 432. In this way, after the coolant enters the first liquid channel 431 through the inlet 41, the coolant is further transported from the bottom end toward the top end, and flows into the second liquid channel 432 through the communication structure of the top-end cover 47. Thereafter, the coolant is transported from the top end to the bottom end in the second liquid channel 432, and finally discharged through the outlet 42. In the embodiment, the coolant flows through the first liquid channel 431 and the second liquid channel 432 in opposite directions, the first heat dissipation surface (i.e., the first surface 440) thermally coupled to the first liquid channel 431 can effectively dissipate the heat generated by the first busbar 10, and the second heat dissipation surface (i.e., the second surface 450) thermally coupled to the second liquid channel 432 can effectively dissipate the heat generated by the second busbar 20. Thus, the one single-structure water-cooling plate 40a can provide effective heat dissipation performance between the two busbars. In addition, the inlet 41 and the outlet 42 for the coolant are connected to the elongated sides of the water-cooling plate 40a, and do not interfere with the connection between the electrical device 9 (referring to FIG. 3) and the front-end plug-in interfaces 8 of the two busbars.

In the embodiment, the liquid cooled busbar assembly 1a further includes an outer housing 50. The outer housing 50 is extended along the first direction (i.e., the Z axial direction), surrounds the first busbar 10, the second busbar 20 and the water-cooling plate 40a, and includes an open end 51. The open end 51 faces the second direction (i.e., the reverse X axial direction), and the second direction is perpendicular to the first direction. The open end 51 is spatially corresponding to the first connection interface 11 and the second connection interface 21, and allows the first connection interface 11 and the second connection interface 21 to be exposed through the open end 51. In the embodiment, the outer housing 50 includes a pair of spacers 52, which are respectively arranged on two opposite sides of the open end 51. The first connection interface 11 and the second connection interface 21 collaboratively form the plug-in interface 8 through the insulation element 30 and the pair of spacers 52. The plug-in interface 8 faces the second direction (i.e., the reverse X axial direction) for connecting the electrical device 9 (referring to FIG. 3). The application of the plurality of electrical devices 9 and the common plug interface 8 is as described above and not redundantly described herein. Furthermore, in the embodiment, the inlet 41 is in communication with the first liquid channel 431 by passing through the outer housing 50, the first busbar 10, and the first surface 440 of the first elongated side plate 44 of the water-cooling plate 40a, and the outlet 42 is in communication with the second liquid channel 432 by passing through the outer housing 50, the second busbar 20, and the second surface 450 of the second elongated side plate 45 of the water-cooling plate 40a, without interfering with the connection between the electrical device 9 and the front-end plug-in interface 8 of the two busbars. In other embodiments, the outer housing 50, the first busbar 10 and the second busbar 20 can also easily avoid the inlet 41 and the outlet 42 at the bottom end and the top end. It should be emphasized that the liquid cooled busbar assembly 1a of the present disclosure utilizes one single-structure water-cooling plate 40a sandwiched between the first busbar 10 and the second busbar 20 to form a cooling system, which has high heat dissipation efficiency, and occupies a smaller space. Moreover, the positions of the inlet 41 and the outlet 42 do not interfere with the use of the front-end plug-in interface 8, and it is easy to further assemble the outer housing 50 to provide the structural support and the protection. Certainly, the present disclosure is not limited thereto.

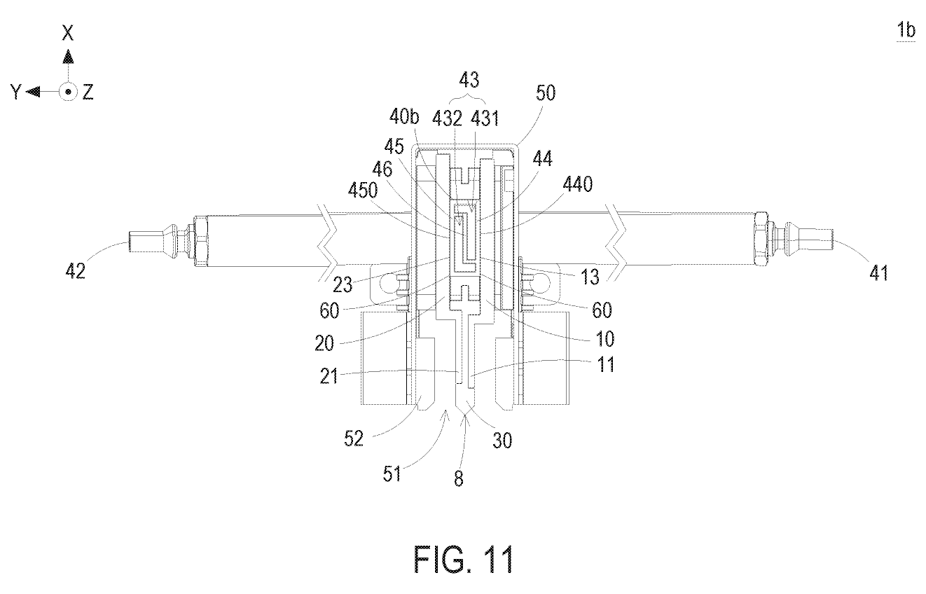

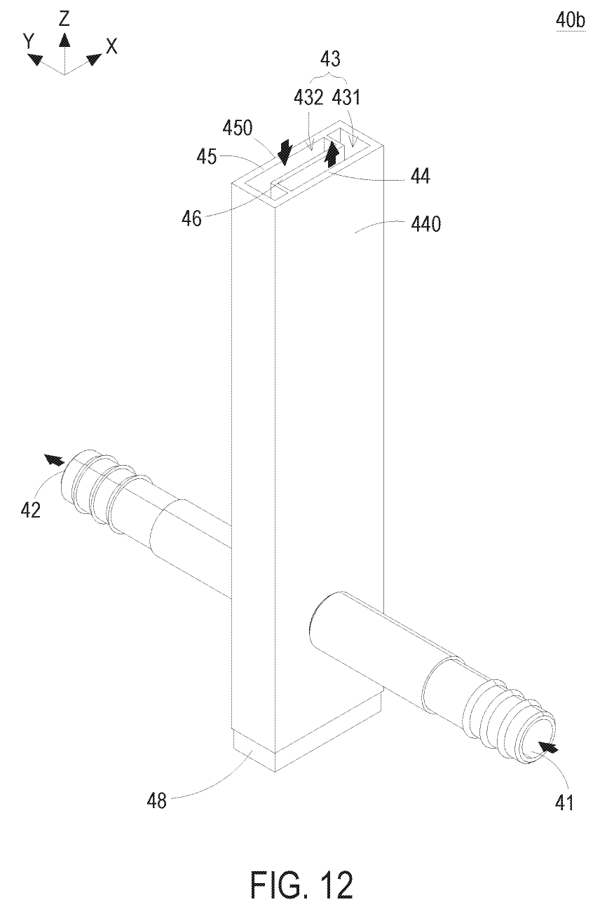

FIG. 11 is a cross-sectional structural view illustrating a liquid cooled busbar assembly according to a third embodiment of the present disclosure. FIG. 12 is a horizontal cross-sectional structure of the water-cooling plate in the liquid cooled busbar assembly according to the third embodiment of the present disclosure. In the embodiment, the structures, elements and functions of the liquid cooled busbar assembly 1b are similar to those of the liquid cooled busbar assembly 1a of FIG. 6 to FIG. 10, and are not redundantly described herein. In the embodiment, the water-cooling plate 40b used in the liquid cooled busbar assembly 1b further includes a partition plate 46. The partition plate 46 is disposed in the at least one liquid channel 43, bent and connected between the first elongated side plate 44 and the second elongated side plate 45. The partition plate 46 divides the at least one liquid channel 43 into a first liquid channel 431 and a second liquid channel 432. The coolant flows through the first liquid channel 431 and the second liquid channel 432 in opposite direction. The first heat dissipation surface (i.e., the first surface 440) thermally coupled to the first liquid channel 431 can effectively dissipate the heat generated by the first busbar 10, and the second heat dissipation surface (i.e., the second surface 450) thermally coupled to the second liquid channel 432 can effectively dissipate the heat generated by the second busbar 20. Thus, the one single-structure water-cooling plate 40b can provide effective heat dissipation performance between the two busbars. Furthermore, the inlet 41 and the outlet 42 of the liquid coolant are connected to the elongated side of the water-cooling plate 40b, and do not interfere with the connection between the electrical device 9 (referring to FIG. 3) and the front-end plug-in interfaces 8 of the two busbars.

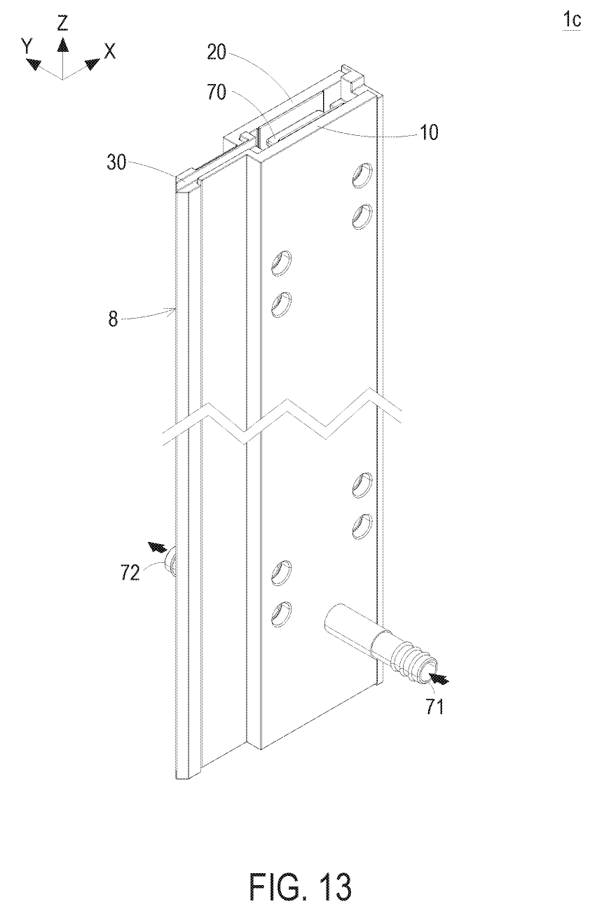

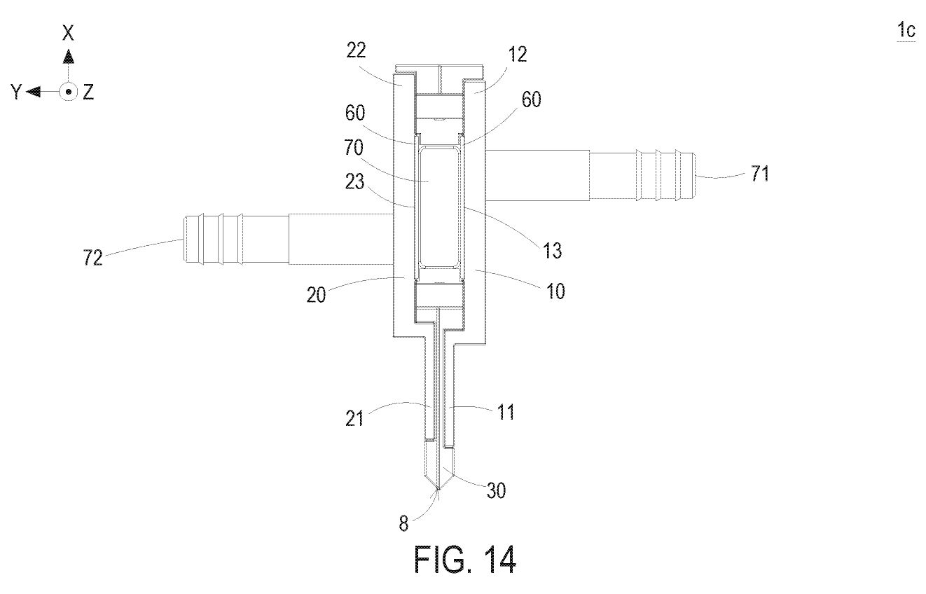

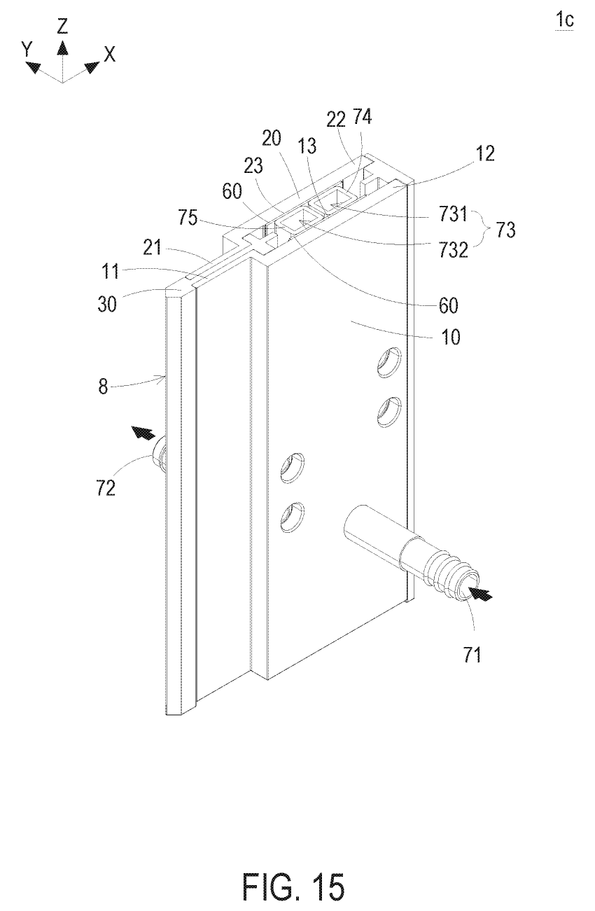

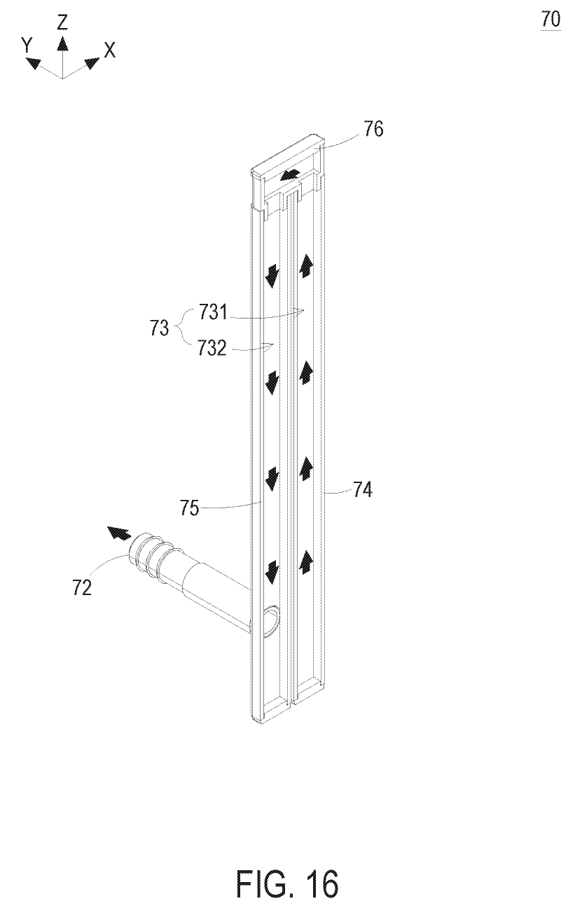

FIG. 13 is a perspective structural view illustrating a liquid cooled busbar assembly according to a fourth embodiment of the present disclosure from a front-end perspective. FIG. 14 is a top view illustrating the liquid cooled busbar assembly according to the fourth embodiment of the present disclosure. FIG. 15 is a cross-sectional structural view illustrating the liquid cooled busbar assembly according to the fourth embodiment of the present disclosure. FIG. 16 is a vertical cross-sectional structure of the water-cooling plate in the liquid cooled busbar assembly according to the fourth embodiment of the present disclosure. In the embodiment, the structures, elements and functions of the liquid cooled busbar assembly 1c are similar to those of the liquid cooled busbar assembly 1a of FIG. 6 to FIG. 10, and are not redundantly described herein. In the embodiment, the water-cooling plate 70 used in the liquid cooled busbar assembly 1c is further formed by a first tube 74 and a second tube 75 arranged side by side and in communication with each other. The at least one liquid channel 73 includes a first liquid channel 731 and a second liquid channel 732. In other words, the first liquid channel 731 in the first tube 74 and the second liquid channel 732 in the second tube 75 are arranged along the second direction (i.e., the reverse X axial direction), located between the lateral side 13 of the first busbar 10 and the lateral side 23 of the second busbar 20, and electrically insulated from the first busbar 10 and the second busbar 20 by the insulation and heat-conductive thermal interface material layer. The water-cooling plate 70 further includes an inlet 71 and an outlet 72 disposed at the bottom end thereof. The coolant is allowed to flow into the water-cooling plate 70 through the inlet 71, flow through the first liquid channel 731 and the second liquid channel 732 thermally coupled with the heat dissipation surface, and then flow out of the water-cooling plate 70 through the outlet 72.

In the embodiment, the inlet 71 is parallel to the third direction (i.e., the Y axial direction), passes through the first busbar 10, and is connected to the bottom end of the first tube 74 to achieve communication with the first liquid channel 731. In addition, the outlet 72 is parallel to the third direction (i.e., the Y axial direction), passes through the second busbar 20 , and is connected to the bottom end of the second tube 75 to achieve communication with the second liquid channel 732. In the embodiment, the water-cooling plate 70 further includes a top-end cover 76 detachably connected to the top end of the water-cooling plate 70. Preferably but not exclusively, the communication structure of the top-end cover 76 allows the first liquid channel 731 and the second liquid channel 732 to communicate with each other. In this way, after the coolant enters the first liquid channel 731 through the inlet 71, the coolant is transported from the bottom end toward the top end and flows into the second liquid channel 732 through the communication structure of the top-end cover 76. Thereafter, the coolant is further transported from the top end to the bottom end in the second liquid channel 732, and finally discharged out of the second liquid channel 732 through the outlet 72. In the embodiment, the coolant flows through the first liquid channel 731 (inside the first tube 74) and the second liquid channel 732 (inside the second tube 75) in opposite directions. The identical sides of the first tube 74 and the second tube 75 attached to the lateral side 13 can effectively dissipate the heat generated by the first busbar 10, and the other sides of the first tube 74 and the second tube 75 attached to the lateral side 23 can effectively dissipate the heat generated by the second busbar 20. Thus, the one single-structure water-cooling plate 70 can provide effective heat dissipation performance between the two busbars. In addition, the inlet 71 and the outlet 42 for the coolant are connected to the elongated sides of the water-cooling plate 40a, without interfering with the connection between the electrical device 9 (referring to FIG. 3) and the front-end plug-in interface 8 of the two busbars.

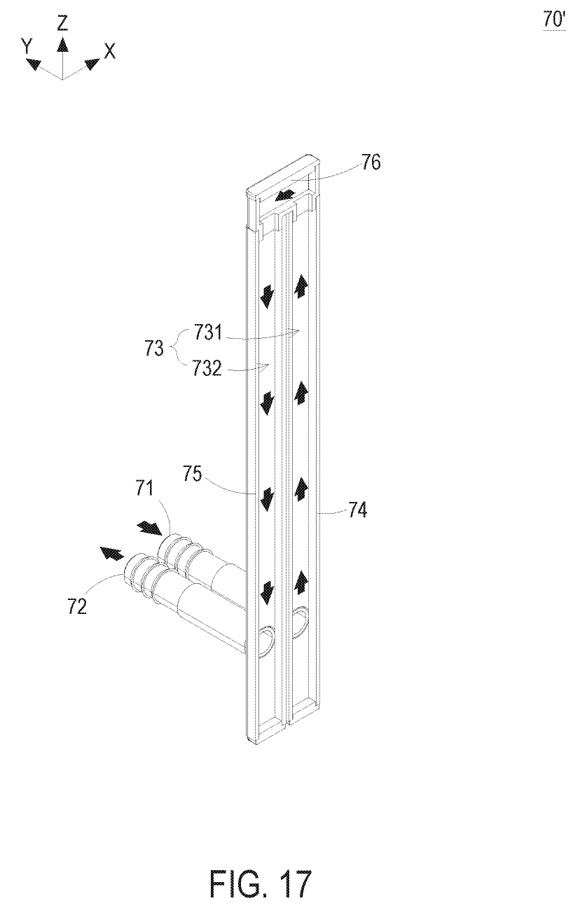

FIG. 17 is a vertical cross-sectional structure of a water-cooling plate in a liquid cooled busbar assembly according to a fifth embodiment of the present disclosure. In the embodiment, the water-cooling plate 70 used in the liquid cooled busbar assembly 1c is replaced with a water-cooling plate 70'. In the embodiment, the inlet 71 is parallel to the third direction (i.e., the Y axial direction), passes through the second busbar 20 , and is connected to the bottom end of the first tube 74 to achieve communication with the first liquid channel 731. In addition, the outlet 72 is parallel to the third direction (i.e., the Y axial direction), passes through the second busbar 20, and is connected to the bottom end of the second tube 75 to achieve communication with the second liquid channel 732. Thus, the inlet 71 and the outlet 72 are integrated on the same lateral side of the second busbar 20 without interfering with the use of the front-end plug-in interface 8. In another embodiment, the inlet 71 and the outlet 72 are be integrated on the same lateral side of the first busbar10 without interfering with the use of the front-end plug-in interface 8. In other embodiments, the first busbar 10 and the second busbar 20 can also easily avoid the inlet 71 and the outlet 72 at the bottom end and the top end. It should be emphasized that the liquid-cooled busbar assembly 1c of the present disclosure utilizes the combination of the one single-structure water-cooling plate 70 sandwiched between the first busbar 10 and the second busbar 20 for cooling, so that the heat dissipation efficiency is greater and the occupied space is smaller. Moreover, the positions of the inlet 71 and the outlet 72 do not interfere with the use of the front-end plug-in interface 8. Certainly, the present disclosure is not limited thereto.

From the above, the liquid cooled busbar assemblies 1, 1a, 1b, 1c of the present disclosure are designed with one single-structure water-cooling plates 40, 40a, 40b, 70, 70', respectively, so that the heat dissipation surface is directly thermally coupled to the first busbar 10 and the second busbar 20 blocked by the insulation element 30, thereby effectively improving the heat dissipation efficiency. The single-structure water-cooling plates 40, 40a, 40b, 70, 70' can be thermally coupled to the opposite lateral sides 13, 23 of the two busbars, or thermally coupled to the rear ends 12, 22 of the two busbars according to the practical requirements, and maintain the electrical insulation with the two busbars to dissipate the heat generated by the two busbars at the same time. Certainly, the positions of the inlets 41, 71 and the outlets 42, 72, and the arrangements of the outer housing 50 corresponding to the first busbar 10 and the second busbar 20 are adjustable according to the practical requirements. The present disclosure is not limited thereto and not redundantly described hereafter.

In summary, the present disclosure provides a liquid cooled busbar assembly having the water-cooling plate with the liquid channel design, so that the heat dissipation surface is directly thermally coupled to the two busbars blocked by the insulation element, and the heat dissipation efficiency is effectively improved. For a liquid cooled busbar assembly extended vertically, a water-cooling plate with one single-structure is provided to be thermally coupled to the opposite inner surfaces of the two busbars, or to be thermally coupled to the rear ends of the two busbars, and the water-cooling plate maintains the electrical insulation with the two busbars. In that, at least one liquid channel of the water-cooling plate allows a coolant to flow through to cool the heat generated by the two busbars simultaneously. When the water-cooling plate with one single structure is thermally coupled to the rear ends of the two busbars through the front end surface, the connection interfaces included in the front ends of the two busbars collaboratively form a plug-in interface through an insulation element for electrical connection of multiple electrical devices vertically arranged. The inlet and the outlet for the coolant are connected to the rear end surface of the water-cooling plate. Preferably but not exclusively, the inlet and the outlet are led in and led out through the bottom end or the top end, and do not interfere with the connection between the electrical devices and the plug-in interface. In addition, when the water-cooling plate with one single-structure is sandwiched between two busbars, the water-cooling plate is designed to have a first liquid channel and a second liquid channel for cooling the two busbars simultaneously. The coolant flows through the first liquid channel and the second liquid channel in opposite directions, respectively, which are in communication, for example, at the top of the water-cooling plate. The first liquid channel and the second liquid channel are formed by two tubes arranged side by side and in communication with each other. Alternatively, the first liquid channel and the second liquid channel are formed by dividing the internal space of the water-cooling plate by a flat partition plate or a bent partition plate. Thereby, the water-cooling plate with one single-structure can provide effective heat dissipation performance between two busbars. In addition, the inlet and the outlet for the coolant are connected through the elongated sides of the water-cooling plate, which does not interfere with the connection of the electrical devices with the front plug-in interfaces of the two busbars. Furthermore, the liquid cooled busbar assembly of the present disclosure utilizes the combination of the one single-structure water-cooling plate and the two busbars to form the cooling system, so that a smaller space is occupied, and the positions of the inlet and the outlet do not interfere with the use of the front-end plug-in interface. It is easy to further assemble an outer housing to provide the structural support and the protection. Certainly, the present disclosure is not limited thereto.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A liquid cooled busbar assembly, comprising:
a first busbar, extended along a first direction and comprising a first connection interface configured to be electrically connected with an electrical device to supply power to the electrical device;
a second busbar, extended along the first direction and comprising a second connection interface configured to be electrically connected with the electrical device to provide a power loop path for the electrical device;
an insulation element, disposed between the first connection interface and the second connection interface to electrically insulate the first connection interface and the second connection interface; and
a water-cooling plate, in contact with rear ends of the first busbar and the second busbar simultaneously, electrically insulated from the first busbar and the second busbar, and comprising a liquid channel extended along the first direction, wherein the liquid channel allows a coolant to flow therethrough to cool the first busbar and the second busbar.

2. The liquid cooled busbar assembly according to claim 1, wherein the insulation element is extended along the first direction, and the first connection interface and the second connection interface collaboratively form a plug-in interface through the insulation element for connecting the electrical device.

3. The liquid cooled busbar assembly according to claim 1, further comprising an inlet and an outlet, wherein the inlet and the outlet are respectively disposed adjacent to a top end and a bottom end of the water-cooling plate, in communication with the at least one liquid channel, and configured to guide the coolant into or out of the at least one liquid channel.

4. The liquid cooled busbar assembly according to claim 3, wherein the water-cooling plate comprises a first elongated side plate and a second elongated side plate, the first elongated side plate and the second elongated side plate are spaced apart from each other in a second direction, the second direction is perpendicular to the first direction, the at least one liquid channel is formed between the first elongated side plate and the second elongated side plate, the first elongated side plate is thermally connected to the rear ends of the first busbar and the second busbars, and the inlet and the outlet are respectively parallel to the second direction and in communication with the at least one liquid channel through the second elongated side plate.

5. The liquid cooled busbar assembly according to claim 3, further comprising an outer housing, wherein the outer housing is extended along the first direction, surrounds the first busbar, the second busbar and the water-cooling plate, and comprises an open end, wherein the open end faces a second direction, and the second direction is perpendicular to the first direction, wherein the open end is spatially corresponding to the first connection interface and the second connection interface, and the first connection interface and the second connection interface are exposed through the open end.

6. The liquid cooled busbar assembly according to claim 5, wherein the outer housing comprises a pair of spacers, which are respectively arranged on two opposite sides of the open end, wherein the first connection interface and the second connection interface collaboratively form a plug-in interface through the insulation element and the pair of spacers, and the plug-in interface faces the second direction for connecting the electrical device.

7. A liquid cooled busbar assembly, comprising:
a first busbar, extended along a first direction and comprising a first connection interface configured to be electrically connected with an electrical device to supply power to the electrical device;
a second busbar, extended along the first direction and comprising a second connection interface configured to be electrically connected with the electrical device to provide a power loop path for the electrical device;
an insulation element, disposed between the first connection interface and the second connection interface to electrically insulate the first connection interface and the second connection interface; and
a water-cooling plate, disposed between the first busbar and the second busbar, electrically insulated from the first busbar and the second busbar, and comprising a liquid channel extended along the first direction, wherein the liquid channel allows a coolant to flow therethrough to cool the first busbar and the second busbar.

8. The liquid cooled busbar assembly according to claim 7, wherein the insulation element is extended along the first direction, and the first connection interface and the second connection interface collaboratively form a plug-in interface through the insulation element for connecting the electrical device.

9. The liquid cooled busbar assembly according to claim 7, wherein the water-cooling plate comprises a first elongated side plate and a second elongated side plate, the first elongated side plate and the second elongated side plate are parallel to a second direction, the second direction is perpendicular to the first direction, and the at least one liquid channel is located between the first elongated side plate and the second elongated side plate, wherein the first elongated side plate and the second elongated side plate respectively form a first heat dissipation surface and a second heat dissipation surface, which are thermally coupled to lateral sides of the first busbar and the second busbar, wherein the first heat dissipation surface and the second heat dissipation surface are two surfaces opposite to each other in a third direction, and the third direction is perpendicular to the second direction and perpendicular to the first direction.

10. The liquid cooled busbar assembly according to claim 9, wherein the water-cooling plate further comprises a partition plate, the partition plate is arranged in the at least one liquid channel and parallel to the first elongated side plate and the second elongated side plate, and the partition plate divides the at least one liquid channel into a first liquid channel and a second liquid channel.

11. The liquid cooled busbar assembly according to claim 9, wherein the water-cooling plate further comprises a partition plate, the partition plate is disposed in the at least one liquid channel, bent and connected between the first elongated side plate and the second elongated side plate, and the partition plate divides the at least one liquid channel into a first liquid channel and a second liquid channel.

12. The liquid cooled busbar assembly according to claim 10, wherein the water-cooling plate further comprises an inlet and an outlet, and the inlet and the outlet are disposed adjacent to a bottom end of the water-cooling plate and in communication with the first liquid channel and the second liquid channel through the first elongated side plate and the second elongated side plate, respectively.

13. The liquid cooled busbar assembly according to claim 10, wherein the water-cooling plate further comprises a top-end cover and a bottom-end cover, and the top-end cover and the bottom-end cover are detachably connected to a top end and a bottom end of the water-cooling plate, respectively, wherein the top-end cover allows the first liquid channel and the second liquid channel to communicate with each other, and the bottom-end cover blocks the first liquid channel and the second liquid channel.

14. The liquid cooled busbar assembly according to claim 7, further comprising an outer housing, wherein the outer housing is extended along the first direction, surrounds the first busbar, the second busbar and the water-cooling plate, and comprises an open end, wherein the open end faces a second direction, and the second direction is perpendicular to the first direction, wherein the open end is spatially corresponding to the first connection interface and the second connection interface, and the first connection interface and the second connection interface are exposed through the open end.

15. The liquid cooled busbar assembly according to claim 14, wherein the outer housing comprises a pair of spacers, which are respectively arranged on two opposite sides of the open end, wherein the first connection interface and the second connection interface collaboratively form a plug-in interface through the insulation element and the pair of spacers, and the plug-in interface faces the second direction for connecting the electrical device.

16. A liquid cooled busbar assembly, comprising:
a water-cooling plate, extended along a first direction and comprising at least one liquid channel, wherein the liquid channel allows a coolant to flow therethrough and forms at least one heat dissipation surface;
a first busbar, extended along a first direction, thermally coupled with the at least one heat dissipation surface, and comprising a first connection interface configured to be electrically connected with an electrical device to supply power to the electrical device; and
a second busbar, extended along the first direction, thermally coupled with the at least one heat dissipation surface, and comprising a second connection interface configured to be electrically connected with the electrical device to provide a power loop path for the electrical device, wherein the first connection interface and the second connection interface are insulated by an insulation element and collaboratively form a plug-in interface for connecting the electrical device;
wherein the water-cooling plate comprises an inlet and an outlet arranged at a bottom end thereof, and the coolant is introduced into the water-cooling plate through the inlet, flows through the at least one heat dissipation surface, and then is discharged out of the water-cooling plate through the outlet.

17. The liquid cooled busbar assembly according to claim 16, wherein the insulation element is extended along the first direction, and the first connection interface and the second connection interface collaboratively form a plug-in interface through the insulation element for connecting the electrical device.

18. The liquid cooled busbar assembly according to claim 16, wherein the at least one liquid channel comprises a first liquid channel and a second liquid channel, and the first liquid channel and the second liquid channel are arranged along a second direction, located between the first busbar and the second busbar, and electrically insulated from the first busbar and the second busbar, wherein the second direction is perpendicular to the first direction, and the coolant flows through the first liquid channel and the second liquid channel in opposite directions.

19. The liquid cooled busbar assembly according to claim 18, wherein the water-cooling plate further comprises a top-end cover detachably connected to a top end of the water-cooling plate, wherein the top-end cover allows the first liquid channel and the second liquid channel to communicate with each other.

20. The liquid cooled busbar assembly according to claim 18, wherein the inlet and the outlet are in communication with the first liquid channel and the second liquid channel through the first busbar and the second busbar, respectively.

21. The liquid cooled busbar assembly according to claim 18, wherein the inlet and the outlet are in communication with the first liquid channel and the second liquid channel, respectively, through the first busbar or the second busbar.
